(19) United States
(12) Patent Application Publication
(10) Pub. No.: US 2015/0299898 A1
(43) Pub. Date: Oct. 22, 2015

(54) SUSCEPTOR PROCESSING METHOD AND SUSCEPTOR PROCESSING PLATE

(71) Applicant: NuFlare Technology, Inc., Yokohama-Shi (JP)

(72) Inventors: Hideki ITO, Yokohama (JP); Hidekazu Tsuchida, Yokosuka (JP); Isaho Kamata, Tokyo (JP); Masahiko Ito, Yokosuka (JP); Hiroaki Fujibayashi, Zushi (JP); Katsumi Suzuki, Nagakute (JP); Koichi Nishikawa, Nagoya (JP)

(21) Appl. No.: 14/677,410

(22) Filed: Apr. 2, 2015

(30) Foreign Application Priority Data
Apr. 16, 2014 (JP) 2014-084467

(51) Int. Cl. C30B 25/12; C30B 29/36; C30B 23/02

(52) U.S. Cl. CPC C30B 25/12; C30B 23/02; C30B 29/36

(57) ABSTRACT

A susceptor processing method according to an embodiment includes: placing a plate on a susceptor arranged in a film forming chamber; heating the susceptor in order to have a temperature higher than that of the plate by using a main heater arranged below the susceptor and an auxiliary heater arranged in an upper part of the film forming chamber, and subliming a SIC film having been formed on a surface of the susceptor and adhering the sublimed SIC on the plate; and transporting the plate from the film forming chamber, the plate having SIC adhered thereon.

### CROSS REFERENCE TO RELATED APPLICATIONS

This application is based upon and claims the benefit of priority from the prior Japanese Patent Application No. 2014-084467, filed on Apr. 16, 2014, the entire contents of which are incorporated herein by reference.

### FIELD

The embodiments of the present invention relate to a susceptor processing method and a susceptor processing plate.

### BACKGROUND

Conventionally, in a manufacturing process of a semiconductor device which requires a crystal film with a relatively large film thickness such as a power device like an IGBT (Insulated Gate Bipolar Transistor), an epitaxial growth technique is used, by which a single crystal thin film is vapor-deposited on a substrate such as a wafer to perform film formation on the substrate.

In a film formation apparatus used for the epitaxial growth technique, for example, a wafer is placed inside a film forming chamber that is kept under a normal pressure or a reduced pressure. Subsequently, while heating the wafer, a gas as a material for film formation (hereinafter, the gas is simply referred to as “material gas”) is supplied in the film forming chamber. As the gas is supplied, a thermal decomposition reaction and a hydrogen reduction reaction of the material gas are caused on the surface of the wafer, and an epitaxial film is formed on the wafer.

In order to manufacture epitaxial wafers having a large film thickness with a high yield, it is necessary to cause a new material gas to continuously come into contact on the surface of a uniformly heated wafer to increase the speed of vapor deposition. Therefore, it is a common practice to perform epitaxial growth while rotating the wafer at a high speed.

In a conventional SIC epitaxial apparatus, an SIC film is deposited not only on a wafer but also on the surface of a susceptor holding the wafer. Because a susceptor having an SIC film deposited on its surface is deformed due to the difference in heat expansion ratios between the surface part and the back surface part of the susceptor, it is not possible to stably hold a wafer thereon, and thus not possible to rotate the wafer at a high speed.

A SIC film adhered on a susceptor as described above, particularly an SiC film adhered on a susceptor formed of a material other than SiC, tends to peel off from the susceptor, so that it can be easily peeled off by using HCl or the like. However, not only the SIC film formed on a susceptor but also an SIC film adhereds on an inner wall of a chamber, as well as SIC formed on SiC parts or SiC-covered parts in a film forming chamber are peeled off, and thus there is a problem that the peeled-off SIC film becomes a particle source.

An object of the present invention is to provide a susceptor processing method and a susceptor processing plate that can remove SiC adhered on a susceptor and can prevent removed SIC from becoming a particle source.

### SUMMARY

A susceptor processing method according to an embodiment includes: placing a plate on a susceptor arranged in a film forming chamber; heating the susceptor in order to have a temperature higher than that of the plate by using a main heater arranged below the susceptor and an auxiliary heater arranged in an upper part of the film forming chamber, and subliming an SIC film having been formed on a surface of the susceptor and adhering the sublimed SIC on the plate; and transporting the plate from the film forming chamber, the plate having SIC adhered thereon.

A susceptor processing plate according to an embodiment, the plate being used to remove an SIC film formed on a surface of a susceptor in a film forming chamber, wherein the plate is formed of carbon, SiC, carbon covered with SiC, or carbon covered with TaC.

### BRIEF DESCRIPTION OF THE DRAWINGS

FIG. 1 is a schematic configuration diagram of a film formation apparatus according to an embodiment;

FIG. 2 is a schematic configuration diagram of the susceptor 102 having the substrate 101 placed thereon;

FIG. 3 is a cross-sectional view of a susceptor processing plate according to an embodiment;

FIGS. 4 to 7 are cross-sectional views of susceptor processing plates according to modifications of the embodiment.

### DETAILED DESCRIPTION

Embodiments will now be explained with reference to the accompanying drawings. The present invention is not limited to the embodiments.

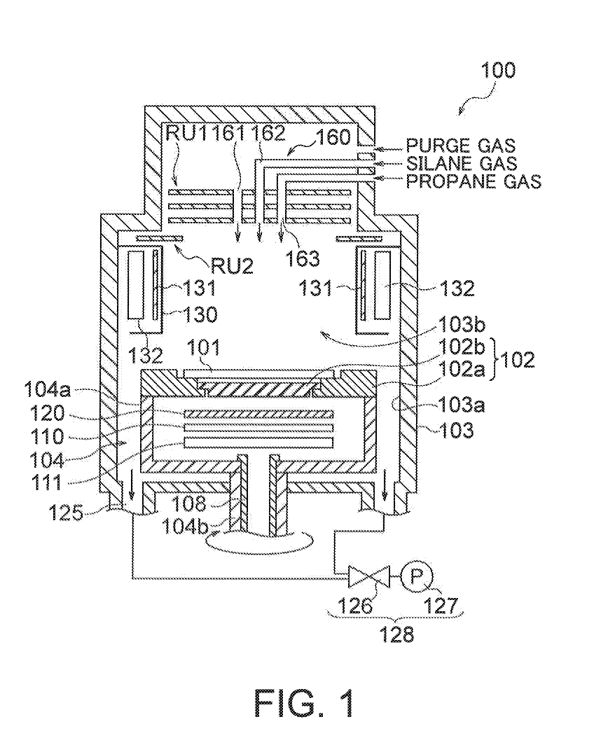

FIG. 1 is a schematic configuration diagram of a film formation apparatus according to an embodiment. As a sample of a film formation processing target, a substrate 101 made of SiC is used. FIG. 1 shows a state where the substrate 101 is placed on a susceptor 102. Plural types of gases (process gases) as materials for forming an SiC epitaxial film are supplied on the substrate 101 placed on the susceptor 102, and then a vapor phase deposition reaction is caused on the substrate 101 to perform film formation.

A film formation apparatus 100 includes a chamber 103 as a film forming chamber in which vapor phase deposition is caused on the substrate 101 to perform film formation of an SiC epitaxial film.

Within the chamber 103, the susceptor 102 is provided in an upper part of a rotation unit 104. The susceptor 102 includes an outer periphery susceptor 102a having a ring shape and being constituted by including an opened part and an internal susceptor 102b that is arranged inside the outer periphery susceptor 102a so as to plug the opened part. A counter sinking is provided on an inner periphery side of the outer periphery susceptor 102a, and the film formation apparatus 100 has a structure in which the outer peripheral part of the substrate 101 is received in the counter sinking so as to support the substrate 101. It is preferable that the susceptor 102 is formed using SiC or TaC. Alternatively, the susceptor 102 can be formed by covering TaC on a carbon surface.

The configuration of the susceptor 102 is not limited to the configuration shown in FIG. 1. For example, the susceptor 102 can have a configuration from which the internal susceptor 102b is omitted.

The rotation unit 104 includes a cylindrical part 104a and a rotation shaft 104b. The rotation unit 104 supports the susceptor 102 in an upper part of the cylindrical part 104a. As the rotation shaft 104b is rotated by a motor (not shown), the susceptor 102 is rotated via the cylindrical part 104a. In this manner, when the substrate 101 is placed on the susceptor 102, the substrate 101 can be rotated.

The cylindrical part 104a has a configuration in which its upper part is openable, and FIG. 1 shows a state where the upper part is opened. A heater (main heater) 120 is provided in the cylindrical part 104a. For example, a resistance heating heater formed of a carbon (C) material doped with impurities is used as the heater 120. Electric power is supplied to the heater 120 by an electrode (not shown) passing through a shaft 108, which is provided in the rotation shaft 104b, made of quartz, and has a substantially cylindrical shape, and the heater 120 heats the substrate 101 from a back surface thereof.

In the cylindrical part 104a, a reflector 110 is provided below the heater 120 in order to efficiently perform heating by the heater 120. The reflector 110 is formed using a material having a high heat resistance such as carbon, SiC, or carbon covered with SIC. Furthermore, a heat insulating member 111 is provided below the reflector 110, and thus it is possible to prevent heat from the heater 120 from being transferred to the shaft 108 and the like, Accordingly, electric power required for the heater 120 at the time of heating can be suppressed.

An elevation pin (not shown) is arranged in the shaft 108, as means for substrate elevation. A lower end of the elevation pin is extended to an elevation device (not shown) provided in a lower part of the shaft 108. With this configuration, the elevation pin can be lifted and lowered by operating the elevation device. The elevation pin is used when the substrate 101 is transported inside the chamber 103 and when the substrate 101 is transported outside the chamber 103. The elevation pin supports and lifts the substrate 101 from below. Subsequently, it is operated that the substrate 101 is held at a predetermined position in an upper part of the rotation unit 104 so that the substrate 101 can be transported and received by a transportation robot (not shown).

Further, the elevation pin is also used when a plate 170 (described later, see FIG. 3) is transported inside the chamber 103 and transported outside the chamber 103.

A gas discharging part 125 for discharging gases is provided in a lower part of the chamber 103. The gas discharging part 125 is connected to a discharging mechanism 128 that is configured by an adjustment valve 126 and a vacuum pump 127. The discharging mechanism 128 is controlled by a control mechanism (not shown) and adjusts the inside of the chamber 103 to have a predetermined pressure.

Furthermore, a cylindrical liner 130 partitioning a film formation area in which film formation processing is performed and a sidewall 103a (an inner wall) of the chamber 103 is provided in the chamber 103. The liner 130 is formed using a material having a high heat resistance such as carbon, SIC, or carbon covered with SIC.

An auxiliary heater 131 that heats the substrate 101 from above is provided between the liner 130 and the sidewall 103a. For example, the auxiliary heater 131 is a resistance heating heater. Furthermore, a heat insulating member 132 is provided between the auxiliary heater 131 and the sidewall 103a, and thus it is possible to prevent heat from the auxiliary heater 131 from being transferred to the chamber 103. With this configuration, electric power required for the auxiliary heater 131 at the time of heating can be suppressed.

In an upper part of the chamber 103 of the film formation apparatus 100, in order to increase thermal efficiency, reflector units RU1 and RU2 that reflect radiation heat from the heater 120 and the auxiliary heater 131 are provided. The reflector unit RU2 is provided below the reflector unit RU1.

The reflector units RU1 and RU2 are formed of a thin plate using carbon, SiC, or carbon covered with SiC. Each of the reflector units RU1 and RU2 can be formed of a single thin plate or of plural laminated thin plates.

As shown in FIG. 1, a gas supply unit 160 is provided in an upper part of the chamber 103 of the film formation apparatus 100. The gas supply unit 160 supplies process gases such as a purge gas or an SIC source gas to a film formation area via gas flow paths (gas pipes) 161 to 163. For example, an argon gas or a hydrogen gas as the purge gas is supplied to a film formation area 103b via the gas flow path 161. A silane gas or a propane gas as the SIC source gas is supplied to the film formation area 103b via the gas flow paths 162 and 163. While one gas flow path is provided to each gas in FIG. 1, the gas flow path can be provided in plural.

A radiation thermometer (not shown) is provided in an upper part of the chamber 103, so that the temperature of the substrate 101 can be measured by the radiation thermometer. In this case, a silica glass window is provided in a part of the chamber 103, and the temperature of the substrate 101 is measured by the radiation thermometer through the silica glass window.

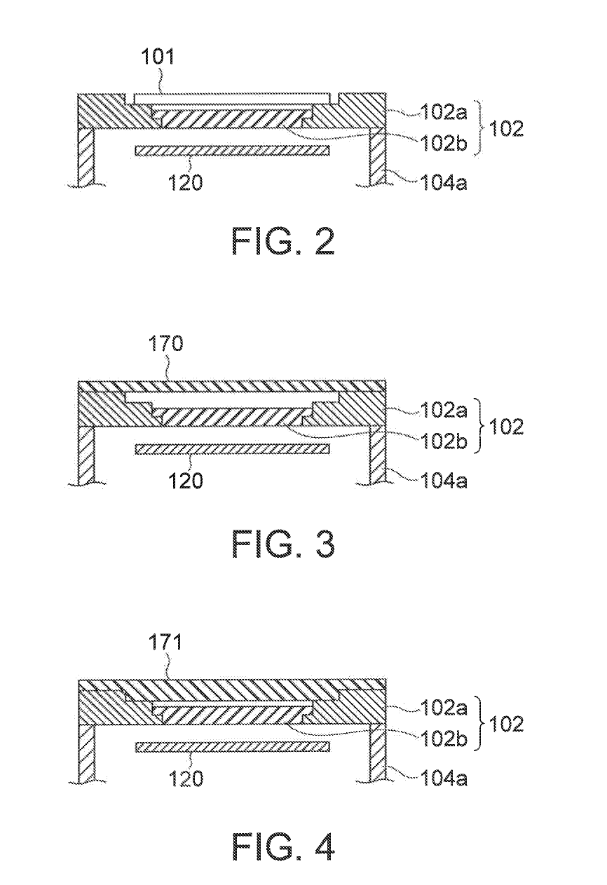

FIG. 2 is a schematic configuration diagram of the susceptor 102 having the substrate 101 placed thereon. When an SIC epitaxial film is formed on the substrate 101, the SIC epitaxial film is formed not only on the substrate 101 but also on a surface of the susceptor 102.

Next, a method of removing an SiC epitaxial film formed on the surface of the susceptor 102 as described above is explained.

First, after forming an SiC epitaxial film on the substrate 101, the substrate 101 is transported outside the chamber 103.

Next, as shown in FIG. 3, the plate 170 is transported inside the chamber 103 and is placed on the susceptor 102. For example, the plate 170 has a size substantially as large as that of the susceptor 102, and is formed of carbon, SiC, carbon covered with SiC, or carbon covered with TaC, with a thickness of approximately 1 mm.

After placing the plate 170 on the susceptor 102, the chamber 103 is heated to a temperature of approximately 1500 to 1700° C., at which SiC sublimes. At this time, it is set that the temperature of the susceptor 102 becomes higher than the temperature of the plate 170 by increasing the output of the heater 120 and suppressing the output of the auxiliary heater 131. For example, it is set that the temperature of the susceptor 102 is higher than the temperature of the plate 170 by approximately 30 to 100° C. At this time, it is preferable that approximately 20 to 100 liter/minute of hydrogen gas is supplied in the chamber 103, and the pressure in the chamber 103 is set to be approximately 50 to 400 Torr.

When SiC sublimes, it adheres (sticks) on a low-temperature object. Therefore, when a SiC film formed on the susceptor 102 sublimes, the sublimed SIC adheres on the plate 170. Further, not only SiC in a part being in contact with the plate 170 but also SiC positioned in the vicinity of the plate 170 adheres on the plate 170 by sublimation. Therefore, SiC formed on the inner peripheral side of the outer periphery susceptor 102a also sublimes and adheres on the plate 170.

With this process, the SiC film formed on the surface of the susceptor 102 can be removed from the susceptor 102.

Thereafter, the temperature in the chamber 103 is lowered to approximately 800° C., and the plate 170 having adhered thereon SiC removed from the susceptor 102 is transported outside the chamber 103.

As described above, according to the present embodiment, by causing the SIC film formed on the susceptor 102 to sublime and to adhere on the plate 170, SIC can be removed from the susceptor 102. Therefore, it is not necessary to remove SIC by etching, and thus it becomes possible to prevent the SIC film formed on the susceptor 102 or on the inner wall 103a of the chamber 103 from being peeled off and becoming a particle source.

In the above embodiment, the plate 170 with a plane shape as shown in FIG. 3 is used; however, as shown in FIG. 4, a plate 171 with a convex shape matching the opened part of the outer periphery susceptor 102a can be also used. By using the plate 171, SIC formed in the opened part of the outer periphery susceptor 102a can be efficiently removed.

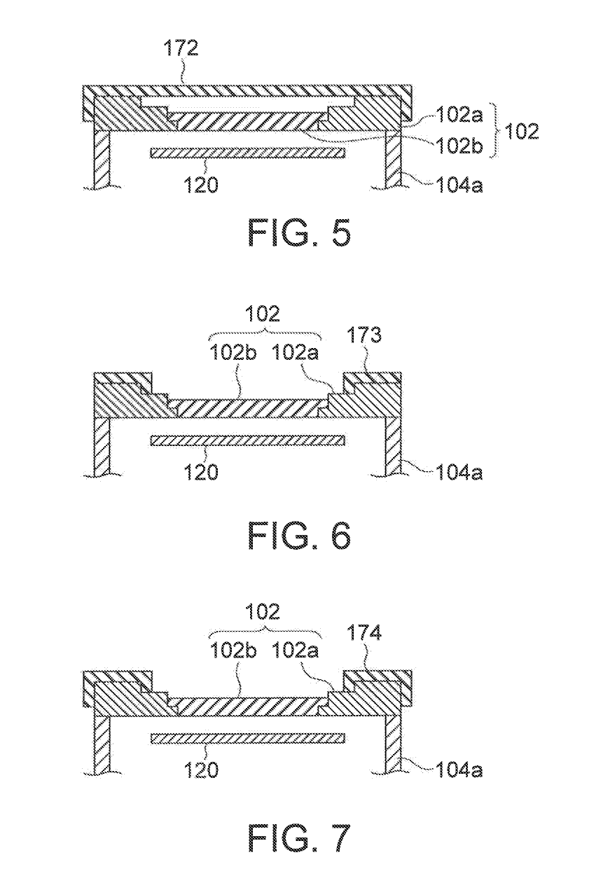

Furthermore, as shown in FIG. 5, a plate 172 with a cup shape covering a top surface and an outer wall surface (an outer peripheral surface) of the outer periphery susceptor 102a can be also used. By using the plate 172, not only SIC formed on the top surface of the outer periphery susceptor 102a but also SIC formed on the outer wall surface of the outer periphery susceptor 102a can be removed.

Further, as shown in FIG. 6, a plate 173 with a ring shape covering the top surface and an inner wall surface (an inner periphery surface) of the outer periphery susceptor 102a can be also used. By using the plate 173, SIC formed in the opened part of the outer periphery susceptor 102a can be efficiently removed.

Further, as shown in FIG. 7, a plate 174 that is a combination of the plate 172 and the plate 173 can be also used.

By using the plate 174, not only SIC formed on the top surface of the outer periphery susceptor 102a but also SIC formed on the outer wall surface of the outer periphery susceptor 102a and SIC formed in the opened part of the outer periphery susceptor 102a can be efficiently removed.

The present invention Is not limited to the above embodiments as they are, and in implementing stages of the invention, the invention can be embodied while modifications are made to constituent elements without departing from the spirit of the invention. Furthermore, various other inventions can be formed by appropriate combinations of a plurality of constituent elements disclosed in the above embodiments, For example, several constituent elements can be omitted from the all constituent elements described in the above embodiments. Further, constituent elements in different embodiments can be combined as appropriate,

1. A susceptor processing method comprising:
placing a plate on a susceptor arranged in a film forming chamber;
heating the susceptor in order to have a temperature higher than that of the plate by using a main heater arranged below the susceptor and an auxiliary heater arranged in an upper part of the film forming chamber, and subliming a SIC film having been formed on a surface of the susceptor and adhering the sublimed SIC on the plate; and
transporting the plate from the film forming chamber, the plate having SIC adhered thereon.

2. The method of claim 1, wherein the susceptor is formed of SIC, TaC, or carbon covered with TaC.

3. The method of claim 1, wherein the plate is formed of carbon, SiC, carbon covered with SIC, or carbon covered with TaC.

4. The method of claim 2, wherein the plate is formed of carbon, SIC, carbon covered with SIC, or carbon covered with TaC.

5. The method of Claim wherein a hydrogen gas is supplied in the film forming chamber during heating by the main heater and the auxiliary heater.

6. The method of claim 2, wherein a hydrogen gas is supplied in the film forming chamber during heating by the main heater and the auxiliary heater.

7. The method of claim 3, wherein a hydrogen gas is supplied in the film forming chamber during heating by the main heater and the auxiliary heater.

8. The method of claim 1, wherein output of the main heater is higher than that of the auxiliary heater, when the SiC film is sublimed.

9. The method of claim 1, wherein a temperature of the film forming chamber is heated to a temperature of approximately 1500 to 1700° C., when the SiC film is sublimed.

10. The method of claim 1, wherein a pressure in the film forming chamber is set to be approximately 50 to 400 Torr, when the SiC film is sublimed.

11. The method of claim 9, wherein a pressure in the film forming chamber is set to be approximately 50 to 400 Torr, when the SIC film is sublimed.

12. A susceptor processing plate used to remove a SIC film formed on a surface of a susceptor in a film forming chamber, wherein the plate is formed of carbon, SIC, carbon covered with SIC, or carbon covered with TaC.

13. The plate of claim 12, wherein the plate has a size substantially as large as that of the susceptor.

14. The plate of claim 12, wherein the plate has a convex shape matching an opened part of the susceptor.

15. The plate of claim 12, wherein the plate has a cup shape covering a top surface and an outer peripheral surface of the susceptor.

16. The plate of claim 12, wherein the plate has a ring shape covering the top surface and an inner periphery surface of the susceptor.

17. The plate of claim 12, wherein the plate has a ring shape covering the top surface and an outer periphery surface of the susceptor.
